(19) United States
(12) Patent Application Publication
(10) Pub. No.: US 2026/0084121 A1
(43) Pub. Date: Mar. 26, 2026

(54) SIMULATION DEVICE FOR GENERATING SUPERSATURATED TOTAL DISSOLVED GAS IN FLOOD DISCHARGE AND ENERGY DISSIPATION REGION OF DAM

(71) Applicant: Changjiang River Scientific Research Institute, Wuhan (CN)

(72) Inventors: Songlin Han, Wuhan (CN); Zhibing Jiang, Wuhan (CN); Duan Chen, Wuhan (CN); Zhixin Wang, Wuhan (CN); Jibin Han, Wuhan (CN); Kunjie Ren, Wuhan (CN); Zibing Cheng, Wuhan (CN); Xiaoxia Hou, Wuhan (CN); Jing Dong, Wuhan (CN); Liguang Qu, Wuhan (CN)

(21) Appl. No.: 19/246,849

(22) Filed: Jun. 24, 2025

(30) Foreign Application Priority Data
Sep. 20, 2024 (CN) 2024113144724

(51) Int. Cl. B01F 23/233; B01F 23/232; B01F 33/45; B01F 35/00; B01F 35/21; B01F 35/221; B01F 35/50; B01F 35/71; B01F 35/90; B01F 35/92; B01F 101/00; G06F 30/28

(52) U.S. Cl. CPC B01F 23/233; B01F 23/232; B01F 33/45; B01F 35/187; B01F 35/189; B01F 35/21112; B01F 35/2112; B01F 35/2113; B01F 35/2115; B01F 35/2211; B01F 35/514; B01F 35/71805; B01F 35/92; G06F 30/28; B01F 2035/99; B01F 2101/305

(57) ABSTRACT

A simulation device for generating a supersaturated total dissolved gas (TDG) in a flood discharge and energy dissipation region of a dam is provided. The simulation device includes a reactor, a water inlet system, a gas inlet system, a venting system, a water drainage and gas exhaust system, a monitoring system, and a control system. An observation window is defined on the reactor, and a magnetic stirring assembly is installed inside the reactor. The cooperation of the water inlet system and the gas inlet system quantitatively controls a mass flow rate of water and gas entering and exiting the reactor, controls the change and variation of a temperature and a pressure inside the reactor, simulates the process of generating supersaturated TDG in the flood discharge and energy dissipation region by injecting water flow with varying air entrainment concentrations, and simulates changes in supersaturated TDG concentrations under varying pressure conditions.

### CROSS-REFERENCE TO RELATED APPLICATION

This application claims priority to Chinese Patent Application No. 202411314472.4, filed on Sep. 20, 2024. The entire contents of the above-mentioned application are incorporated herein by reference.

### TECHNICAL FIELD

The disclosure relates to the technical field of hydraulic and hydropower engineering and water environment engineering, and more particularly to a simulation device for generating a supersaturated total dissolved gas in a flood discharge and energy dissipation region of a dam.

### BACKGROUND

In recent years, an increasing number of high dams and large reservoirs have been constructed and put into operation. Ecological and environmental issues caused by the operation of the high dams have attracted increasing attention from scholars and society. When the high dam discharges flood water, a surface of a discharged water tongue is intensely mixed with air and then enters into a depth of a downstream water cushion pond or a dissipation pond, causing a total dissolved gas (TDG) in a water body to exceed a relative saturation at a local atmospheric pressure, and forming a TDG supersaturated water body. As the water body moves downstream, the supersaturated TDG can adversely affect aquatic organisms such as fish in the river, leading to “gas bubble disease” and even mass mortality of the fish. Currently, there is a lack of corresponding simulation devices for the study of the supersaturated TDG. In view of this, the disclosure provides a simulation device for generating a supersaturated TDG in a flood discharge and energy dissipation region of a dam to fill a gap in the related art.

### SUMMARY

A purpose of the disclosure is to provide a simulation device for generating a supersaturated total dissolved gas (TDG) in a flood discharge and energy dissipation region of a dam, so as to solve problems in the related art.

Specifically, a simulation device for generating a supersaturated TDG in a flood discharge and energy dissipation region of a dam is provided, including a high-pressure reactor, a water inlet system, a gas inlet system, a venting system, a water drainage and gas exhaust system, a monitoring system, and a control system.

The water inlet system includes a water supply unit and a connecting pipe, an output end of the water supply unit is fixedly connected to an end of the connecting pipe, and another end of the connecting pipe extends into the high-pressure reactor.

An output end of the gas inlet system is fixedly connected to the connecting pipe.

The venting system includes a venting unit and a tailrace pool, an end of the venting unit is fixedly connected to a bottom of the high-pressure reactor, and another end of the venting system is fixedly connected to the tailrace pool.

The water drainage and gas exhaust system is installed at the bottom of the high-pressure reactor, the water drainage and gas exhaust system is fixedly connected to the high-pressure reactor, and an end of the water drainage and gas exhaust system is fixedly connected to the tailrace pool.

The monitoring system is installed inside the high-pressure reactor to monitor a temperature, a pressure, and a liquid level within the high-pressure reactor.

The water inlet system, the gas inlet system, the venting system, and the monitoring system are all electrically connected to the control system.

An observation window is defined on a body of the high-pressure reactor, and a magnetic stirring assembly is installed inside the high-pressure reactor.

In an embodiment, the water supply unit includes a water tank, the water tank is fixedly connected to a water delivery pipeline, and an end of the water delivery pipeline is fixedly connected to the connecting pipe. A constant flux pump, a water inlet valve, and a first flow meter are installed on the water delivery pipeline sequentially in that order along a water supply direction.

In an embodiment, the gas inlet system includes an air compressor, an output end of the air compressor is fixedly connected to a gas delivery pipeline, and an end of the gas delivery pipeline is fixedly connected to the connecting pipe. An air inlet valve and a second flow meter are installed on the gas delivery pipeline sequentially in that order along a gas supply direction.

In an embodiment, a filter mesh is installed inside the connecting pipe, and the filter mesh is located between an end of the gas delivery pipeline and an opening of the high-pressure reactor.

In an embodiment, the venting unit includes a first drainage pipe, an end of the first drainage pipe is fixedly connected to the bottom of the high-pressure reactor, another end of the first drainage pipe is fixedly connected to the tailrace pool, and a solenoid valve is installed on the first drainage pipe.

In an embodiment, the water drainage and gas exhaust system includes a second drainage pipe and a gas exhaust pipe. An end of the second drainage pipe is fixedly connected to the bottom of the high-pressure reactor, and another end of the second drainage pipe is fixedly connected to the tailrace pool. An end of the gas exhaust pipe is fixedly connected to a top of the high-pressure reactor, and another end of the gas exhaust pipe is fixedly connected to a middle part of the second drainage pipe. The second drainage pipe is equipped with a drainage valve and a back pressure valve. The drainage valve is disposed between the gas exhaust pipe and the end of the second drainage pipe close to the high-pressure reactor. The back pressure valve is disposed between the gas exhaust pipe and an end of the second drainage pipe facing away from the high-pressure reactor, and a gas exhaust valve is installed on the gas exhaust pipe.

In an embodiment, the monitoring system includes a temperature sensor, a pressure sensor, a liquid level indicator, and a total dissolved gas pressure measurement system. The temperature sensor, the pressure sensor, the liquid level indicator, and the total dissolved gas pressure measurement system are all electrically connected to the control system.

In an embodiment, a heating assembly is installed on the high-pressure reactor.

In an embodiment, a high-speed camera is installed on the observation window.

The disclosure has technical effects as follows.

In the simulation device of the disclosure, the cooperation of the water inlet system and the gas inlet system quantitatively controls the mass flow rate of water and gas entering and exiting the high-pressure reactor, controls the change and variation of the temperature and the pressure inside the high-pressure reactor, simulates the process of generating supersaturated TDG in the flood discharge and energy dissipation region by injecting water flow with varying air entrainment concentrations, and simulates changes in supersaturated TDG concentration under varying pressure conditions, and monitors the distribution characteristics of bubbles in the water during the generation process of the supersaturated gas.

In the disclosure, the monitoring system is arranged in the high-pressure reactor, so that the supersaturation of gas in a tank of the high-pressure reactor can be measured in real time, greatly reducing the error caused by gas release during the process of water being discharged from the tank of the high-pressure reactor, and the obtained data is truer and more effective.

### BRIEF DESCRIPTION OF DRAWINGS

Features and advantages of the disclosure will be more clearly understood by reference to the accompanying drawings, which are given by way of illustration and are not to be construed as limiting the disclosure in any way.

FIG. 1 illustrates a schematic structural diagram of a simulation device for generating a supersaturated TDG in a flood discharge and energy dissipation region of a dam.

FIG. 2 illustrates a variation of TDG with time in a reactor at a pressure of 0.5 megapascals (MPa).

### DESCRIPTION OF REFERENCE SIGNS

1—water tank; 2—tailrace pool; 3—constant flux pump; 4—air compressor; 5—high-pressure reactor; 6—filter mesh; 7—magnetic stirring assembly; 8—water inlet valve; 9—air inlet valve; 10—gas exhaust valve; 11—back pressure valve; 12—drainage valve; 13—solenoid valve; 14—first flow meter; 15—second flow meter; 16—pressure sensor; 17—temperature sensor; 18—total dissolved gas pressure measurement system; 19—liquid level indicator; 20—observation window; 21—camera; 22—water delivery pipeline; 23—gas delivery pipeline; 24—first drainage pipe; 25—second drainage pipe; 26—control system; 27—connecting pipe; 28—gas exhaust pipe.

### DETAILED DESCRIPTION OF EMBODIMENTS

In order to make purposes, technical solutions and advantages of embodiments of the disclosure clearer, the technical solutions in the embodiments of the disclosure will be described clearly and completely in combination with the drawings attached to the embodiments of the disclosure. Apparently, the illustrated embodiments are a part of the embodiments of the disclosure, but not all of the whole embodiments. Based on the embodiments of the disclosure, all other embodiments obtained by those skilled in the art without creative work are within the scope of the disclosure.

In order to make the above purposes, features and advantages of the disclosure more apparent and easier to understand, the following is a further detailed description of the disclosure in combination with the attached drawings and specific embodiments.

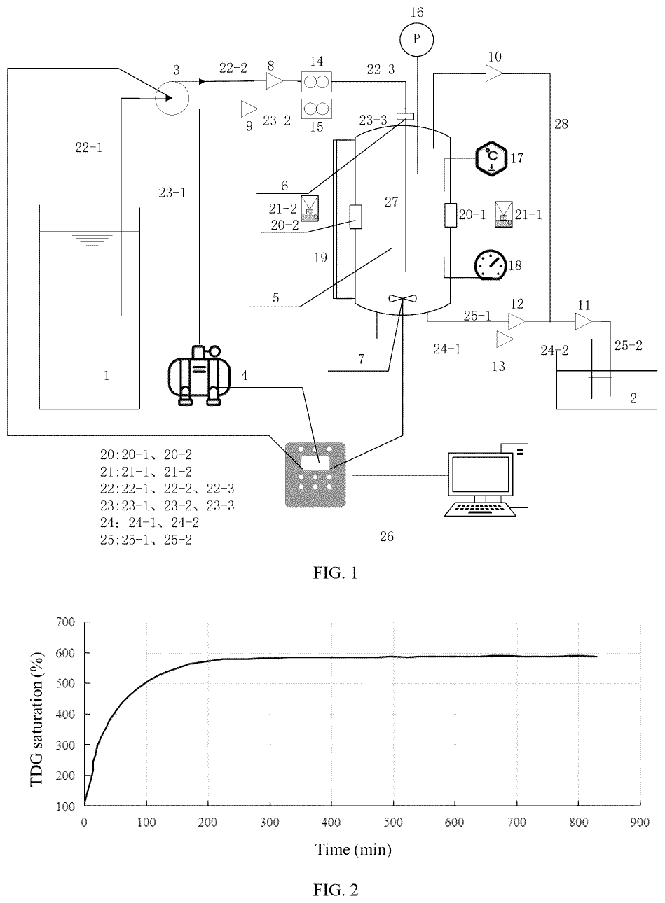

As shown in FIG. 1, the disclosure provides a simulation device for generating a supersaturated total dissolved gas (TDG) in a flood discharge and energy dissipation region of a dam, which includes a high-pressure reactor 5, a water inlet system, a gas inlet system, a venting system, a water drainage and gas exhaust system, a monitoring system and a control system 26.

The water inlet system includes a water supply unit and a connecting pipe 27. An output end of the water supply unit is fixedly connected to an end of the connecting pipe 27, and another end of the connecting pipe 27 extends into the high-pressure reactor 5. A water mixing valve is arranged at a connection position between the connecting pipe 27 and the high-pressure reactor 5 to mix water flow and gas from the water supply unit and gas inlet system into the high-pressure reactor 5.

An output end of the gas inlet system is fixedly connected to the connecting pipe 27.

The venting system includes a venting unit and a tailrace pool 2. An end of the venting unit is fixedly connected to a bottom of the high-pressure reactor 5, and another end of the venting system is fixedly connected to the tailrace pool 2.

The water drainage and gas exhaust system is installed at the bottom of the high-pressure reactor 5 and the water drainage and gas exhaust system is fixedly connected to the high-pressure reactor 5. An end of the water drainage and gas exhaust system is fixedly connected to the tailrace pool 2.

The monitoring system is installed inside the high-pressure reactor 5 to monitor a temperature, a pressure, and a liquid level in the high-pressure reactor 5.

The control system 26 is electrically connected to the water inlet system, the gas inlet system, the venting system, and the monitoring system.

The control system 26 can be set according to specific application environments, such as using a single-chip microcomputer, a programmable logic controller (PLC), advanced reduced instruction set computer (RISC) machine (ARM), a field-programmable gate array (FPGA), or other control methods. No specific limitations are made in this embodiment.

An observation window 20 is defined on a body of the high-pressure reactor 5 and a magnetic stirring assembly 7 is installed inside the high-pressure reactor 5.

When the simulation device of the disclosure operates, through the cooperation of the water inlet system and the gas inlet system, a mass flow rate of water and gas entering and exiting the high-pressure reactor 5 can be quantitatively controlled, and the maintenance of constant temperature and pressure and the control of their variations are achieved within the high-pressure reactor 5. The process of generating supersaturated TDG in the water body of the flood discharge and energy dissipation region by injecting water flow with varying air entrainment concentrations is simulated, and changes in supersaturated TDG concentrations under varying pressure conditions are simulated. The distribution characteristics of bubbles in the water body during the generation process of the supersaturated gas is monitored.

The monitoring system is installed inside the high-pressure reactor 5 to measure a supersaturation of the gas inside the high-pressure reactor 5 in real-time, significantly reducing errors caused by gas release during the discharge of water from the high-pressure reactor 5, which results in more accurate and reliable data.

The magnetic stirring assembly 7 can reach a maximum rotate speed of 750 revolutions per minute (r/min) to stir the solution inside the high-pressure reactor 5, ensuring thorough gas dissolution. The observation window 20 allows experimenters to observe a gas-liquid morphology inside the high-pressure reactor 5.

In an embodiment, the water supply unit includes a water tank 1, the water tank 1 is fixedly connected to a water delivery pipeline 22, an end of the water delivery pipeline 22 is connected to the connecting pipe 27, and a constant flux pump 3, a water inlet valve 8, and a first flow meter 14 are installed on the water delivery pipeline 22 sequentially in that order along a water supply direction.

The constant flux pump 3 is capable of a constant flow rate of water injection into the high-pressure reactor 5. A flow rate of the injected water can be compared with that displayed by the constant flux pump 3 through the setting of the first flow meter 14, thereby accurately showing the flow rate of the injected water. The water pumping efficiency of the constant flux pump 3 ranges from 0.1 to 30,000 milliliters per minute (mL/min).

In an embodiment, the gas inlet system includes an air compressor 4, an output end of the air compressor 4 is fixedly connected to a gas delivery pipeline 23, an end of the gas delivery pipeline 23 is fixedly connected to the connecting pipe 27, and an air inlet valve 9 and a second flow meter 15 are installed on the gas delivery pipeline 23 sequentially in that order along a gas supply direction.

The second flow meter 15 uses a gas mass flowmeter, by setting the gas mass flowmeter, a constant flow gas can be injected into the high-pressure reactor 5.

In an embodiment, a filter mesh 6 is installed inside the connecting pipe 27, the filter mesh 6 is located between an end of the gas delivery pipeline 23 and an opening of the high-pressure reactor 5.

The filter mesh 6 can be replaced with screens of different mesh sizes to inject bubbles of a variety of sizes and gas mixtures into the high-pressure reactor 5.

In an embodiment, the venting system includes a first drainage pipe 24, an end of the first drainage pipe 24 is fixedly connected to the bottom of the high-pressure reactor 5 and another end of the first drainage pipe 24 is fixedly connected to the tailrace pool 2, and a solenoid valve 13 is installed on the first drainage pipe 24.

By controlling an opening and closing of the first drainage pipe 24 through the solenoid valve 13, the air and the water inside the high-pressure reactor 5 can be discharged completely after an experiment is completed, making it easy to quickly empty the high-pressure reactor 5.

In an embodiment, the water drainage and gas exhaust system includes a second drainage pipe 25 and a gas exhaust pipe 28, an end of the second drainage pipe 25 is fixedly connected to the bottom of the high-pressure reactor 5, and another end of the second drainage pipe 25 is fixedly connected to the tailrace pool 2. An end of the gas exhaust pipe 28 is fixedly connected to a top of the high-pressure reactor 5, and another end of the gas exhaust pipe 28 is fixedly connected to a middle part of the second drainage pipe 25. The second drainage pipe 25 is equipped with a drainage valve 12 and a back pressure valve 11. The drainage valve 12 is disposed between the gas exhaust pipe 28 and an end of the second drainage pipe 25 close to the high-pressure reactor 5, the back pressure valve 11 is disposed between the gas exhaust pipe 28 and an end of the second drainage pipe 25 facing away from the high-pressure reactor 5, and a gas exhaust valve 10 is installed on the gas exhaust pipe 28.

By setting the back pressure valve 11, an internal pressure of the high-pressure reactor 5 can be maintained constant while the water or the gas continues to flow into the high-pressure reactor 5. The drainage valve 12 controls a discharge of water from the high-pressure reactor 5 and the gas exhaust valve 10 controls an exhausting of gas from the high-pressure reactor 5.

In an embodiment, the monitoring system includes a temperature sensor 17, a pressure sensor 16, a liquid level indicator 19, and a total dissolved gas pressure measurement system 18, all of which are electrically connected to the control system 26.

The temperature sensor 17 is configured to detect a water body temperature inside the high-pressure reactor 5, and the temperature is controlled in a range of 15° C. to 60° C.

The total dissolved gas pressure measurement system 18 can transmit real-time data on the total dissolved gas pressure in the water body to a computer, and the total dissolved gas pressure measurement system uses techniques in the related art.

The setting of the pressure sensor 16 can record changes in pressure inside the high-pressure reactor 5.

The liquid level of the water body in the high-pressure reactor 5 can be displayed through the setting of the liquid level indicator 19.

In an embodiment, the high-pressure reactor 5 is equipped with a heating assembly. The temperature of the water body in the high-pressure reactor 5 can be controlled through the heating assembly. The heating assembly uses techniques in the related art such as electromagnetic heating or other methods, with no specific limitations in this embodiment.

In an embodiment, a high-speed camera 21 is installed on the observation window 20. By setting up the high-speed camera 21, the water body in the high-pressure reactor 5 can be photographed, and the bubble size characteristics and air entrainment concentrations in the water body can be analyzed.

In the description of the disclosure, it should be understood that terms “longitudinal”, “lateral”, “upper”, “lower”, “front”, “rear”, “left”, “right”, “vertical”, “horizontal”, “top”, “bottom”, “inner”, “outer”, etc., indicating an orientation or positional relationship are based on the orientation or positional relationship shown in the drawings, and are only for the convenience of describing the disclosure. It is not intended to indicate or imply that devices or elements referred to must have a particular orientation, be constructed or operate in a particular orientation, and therefore, should not be construed as limiting the disclosure.

The above embodiments are illustrative only of the disclosure and are not used to limit the disclosure, those skilled in the art may make various modifications and variations without deviating from the spirit and scope of the disclosure, and such modifications and variations fall within the limits of the appended claims.

What is claimed is:

1. A simulation device for generating a supersaturated total dissolved gas in a flood discharge and energy dissipation region of a dam, comprising:
a reactor (5);
a water inlet system, comprising: a water supply unit and a connecting pipe (27), wherein an output end of the water supply unit is fixedly connected to an end of the connecting pipe (27), and another end of the connecting pipe (27) extends into the reactor (5);
a gas inlet system, wherein an output end of the gas inlet system is fixedly connected to the connecting pipe (27);
a venting system, comprising: a venting unit and a tailrace pool (2), wherein an end of the venting unit is fixedly connected to a bottom of the reactor (5), and another end of the venting system is fixedly connected to the tailrace pool (2);
a water drainage and gas exhaust system, installed at the bottom of the reactor (5), wherein the water drainage and gas exhaust system is fixedly connected to the reactor (5), and an end of the water drainage and gas exhaust system is fixedly connected to the tailrace pool (2);
a monitoring system, installed inside the reactor (5), wherein the monitoring system is configured to monitor a temperature, a pressure, and a liquid level within the reactor (5); and
a control system (26), wherein the water inlet system, the gas inlet system, the venting system, and the monitoring system are all electrically connected to the control system (26); and
wherein an observation window (20) is defined on a body of the reactor (5), and a magnetic stirring assembly (7) is installed inside the reactor (5).

2. The simulation device as claimed in claim 1, wherein the water supply unit comprises a water tank (1), the water tank (1) is fixedly connected to a water delivery pipeline (22), an end of the water delivery pipeline (22) is fixedly connected to the connecting pipe (27); and a constant flux pump (3), a water inlet valve (8), and a first flow meter (14) are installed on the water delivery pipeline (22) sequentially in that order along a water supply direction.

3. The simulation device as claimed in claim 1, wherein the gas inlet system comprises an air compressor (4), an output end of the air compressor (4) is fixedly connected to a gas delivery pipeline (23), an end of the gas delivery pipeline (23) is fixedly connected to the connecting pipe (27); and an air inlet valve (9) and a second flow meter (15) are installed on the gas delivery pipeline (23) sequentially in that order along a gas supply direction.

4. The simulation device as claimed in claim 3, wherein a filter mesh (6) is installed inside the connecting pipe (27), and the filter mesh (6) is located between an end of the gas delivery pipeline (23) and an opening of the reactor (5).

5. The simulation device as claimed in claim 1, wherein the venting unit comprises a first drainage pipe (24), an end of the first drainage pipe (24) is fixedly connected to the bottom of the reactor (5), another end of the first drainage pipe (24) is fixedly connected to the tailrace pool (2), and a solenoid valve (13) is installed on the first drainage pipe (24).

6. The simulation device as claimed in claim 1, wherein the water drainage and gas exhaust system comprises a second drainage pipe (25) and a gas exhaust pipe (28); an end of the second drainage pipe (25) is fixedly connected to the bottom of the reactor (5), and another end of the second drainage pipe (25) is fixedly connected to the tailrace pool (2); an end of the gas exhaust pipe (28) is fixedly connected to a top of the reactor (5), and another end of the gas exhaust pipe (28) is fixedly connected to a middle part of the second drainage pipe (25); the second drainage pipe (25) is equipped with a drainage valve (12) and a back pressure valve (11); the drainage valve (12) is disposed between the gas exhaust pipe (28) and the end of the second drainage pipe (25) close to the reactor (5); the back pressure valve (11) is disposed between the gas exhaust pipe (28) and an end of the second drainage pipe (25) facing away from the reactor (5); and a gas exhaust valve (10) is installed on the gas exhaust pipe (28).

7. The simulation device as claimed in claim 1, wherein the monitoring system comprises a temperature sensor (17), a pressure sensor (16), a liquid level indicator (19), and a total dissolved gas pressure measurement system (18); the temperature sensor (17), the pressure sensor (16), the liquid level indicator (19), and the total dissolved gas pressure measurement system (18) are all electrically connected to the control system (26).

8. The simulation device as claimed in claim 1, wherein a heating assembly (17) is installed on the reactor (5).

9. The simulation device as claimed in claim 1, wherein a camera (21) is installed on the observation window (20).
